(19) United States
(12) Patent Application Publication
(10) Pub. No.: US 2018/0315894 A1
(43) Pub. Date: Nov. 1, 2018

(54) SEMICONDUCTOR DEVICE PACKAGE AND A METHOD OF MANUFACTURING THE SAME

(71) Applicant: Advanced Semiconductor Engineering, Inc., Kaohsiung (TW)

(72) Inventors: Hsin-Ying HO, Kaohsiung (TW); Hsun-Wei CHAN, Kaohsiung (TW); Tsung-Yu LIN, Kaohsiung (TW)

(73) Assignee: Advanced Semiconductor Engineering, Inc., Kaohsiung (TW)

(21) Appl. No.: 15/909,884

(22) Filed: Mar. 1, 2018

Related U.S. Application Data
(60) Provisional application No. 62/490,571, filed on Apr. 26, 2017.

(51) Int. Cl. H01L 33/48; H01L 33/62; H01L 33/00; H01L 31/0203; H01L 31/18; H01L 31/02

(52) U.S. Cl. CPC H01L 33/483; H01L 33/62; H01L 31/02005; H01L 31/0203; H01L 31/18; H01L 33/005

(57) ABSTRACT

A semiconductor device package includes a carrier, a semiconductor device disposed on the carrier, and a lid disposed on the semiconductor device. The lid is spaced from the carrier by a first distance. The lid includes a base portion, a first pin extending from the base portion toward the semiconductor device, and a transparent portion. The first pin is spaced from the carrier by a second distance.

### CROSS-REFERENCE TO RELATED APPLICATION

This application claims the benefit of and priority to U.S. Provisional Application No. 62/490,571, filed Apr. 26, 2017, the content of which is incorporated herein by reference in its entirety.

### BACKGROUND

### 1. Technical Field

The present disclosure relates to a semiconductor device package including a lid adjacent to a carrier, and to a semiconductor device package including a lid that includes a first extension portion with a first length and a second extension portion with a second length, the first length of the first extension portion being greater than the second length of the second extension portion.

### 2. Description of the Related Art

Some semiconductor device packages include a semiconductor device (e.g. a sensor, a die, or a chip), a lid, and a lens disposed on the lid. However, a performance of the semiconductor device package may be deteriorated by inaccuracy during the process of manufacturing the semiconductor device package (e.g. misalignment between components being greater than a manufacturing tolerance of the components).

### SUMMARY

In some embodiments, according to one aspect, a semiconductor device package includes a carrier, a semiconductor device disposed on the carrier, and a lid disposed on the semiconductor device. The lid is spaced from the carrier by a first distance. The lid includes a base portion, a first pin extending from the base portion toward the semiconductor device, and a transparent portion. The first pin is spaced from the carrier by a second distance.

In some embodiments, according to another aspect, a semiconductor device package includes a carrier, a semiconductor device module disposed on the carrier, and a lid covering and surrounding the semiconductor device module. The lid includes a base portion, a pin extending from the base portion toward the semiconductor device module and a transparent portion. The pin contacts the semiconductor device module.

In some embodiments, according to another aspect, a semiconductor device package includes a carrier, a semiconductor device disposed on the carrier, and a lid adjacent to the carrier. The lid includes a base portion, a first extension portion with a first length, a second extension portion with a second length, and a transparent portion. The first extension portion and the second extension portion extend from the base portion toward the carrier. The first length of the first extension portion is greater than the second length of the second extension portion.

In some embodiments, according to another aspect, a method for manufacturing a semiconductor device package includes: providing a carrier and a semiconductor device module; and providing a lid on the semiconductor device module, the lid being spaced from the carrier by a gap. The lid includes a plurality of pins protruding toward the semiconductor device module. The plurality of pins contact the semiconductor device module.

### BRIEF DESCRIPTION OF THE DRAWINGS

FIG. 1A illustrates a cross-sectional view of a semiconductor device package according to some embodiments of the present disclosure.

FIG. 1B illustrates a cross-sectional view of a semiconductor device package according to some embodiments of the present disclosure.

FIG. 1C illustrates a perspective view of a lid according to some embodiments of the present disclosure.

FIG. 1D illustrates a perspective view of a lid according to some embodiments of the present disclosure.

FIG. 1E illustrates a perspective view of a lid according to some embodiments of the present disclosure.

FIG. 2A illustrates a cross-sectional view of a semiconductor device package according to some embodiments of the present disclosure.

FIG. 2B illustrates a cross-sectional view of a semiconductor device package according to some embodiments of the present disclosure.

FIG. 3 illustrates a method of manufacturing a semiconductor device package according to some embodiments of the present disclosure.

FIG. 4 illustrates a method of manufacturing a semiconductor device package according to some embodiments of the present disclosure.

FIG. 5 illustrates a cross-sectional view of a comparative semiconductor device package.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are specified with respect to a certain component or group of components, or a certain plane of a component or group of components, for the orientation of the component(s) as shown in the associated figure. It should be understood that the spatial descriptions used herein are for purposes of illustration only, and that practical implementations of the structures described herein can be spatially arranged in any orientation or manner, provided that the merits of embodiments of this disclosure are not deviated from by such arrangement.

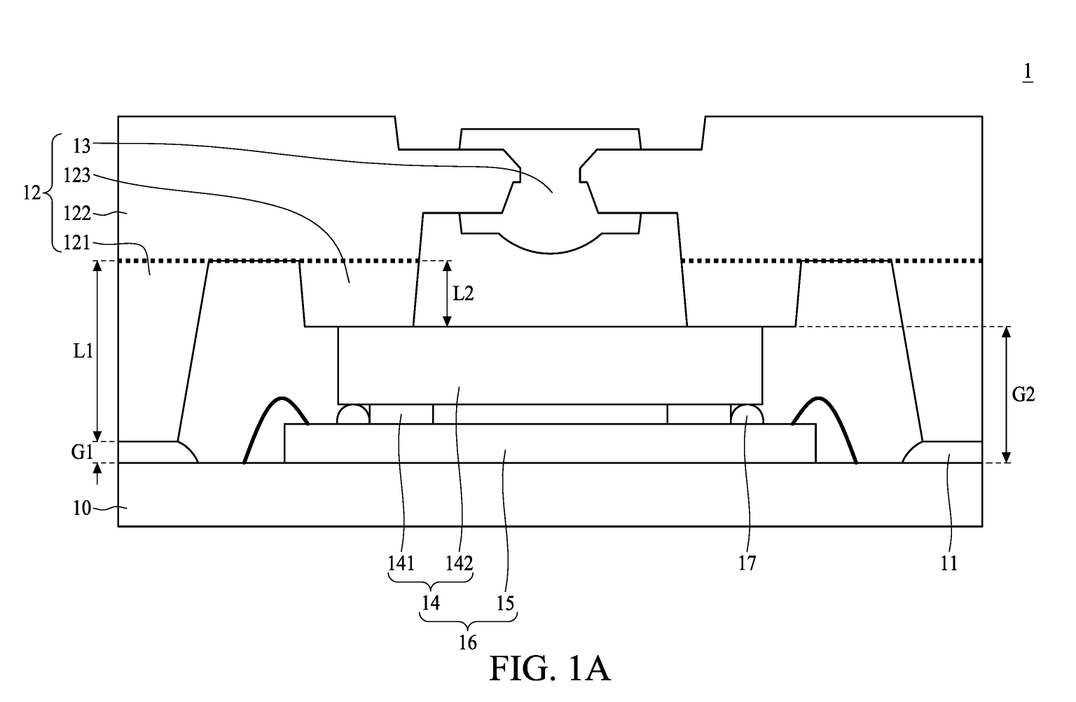

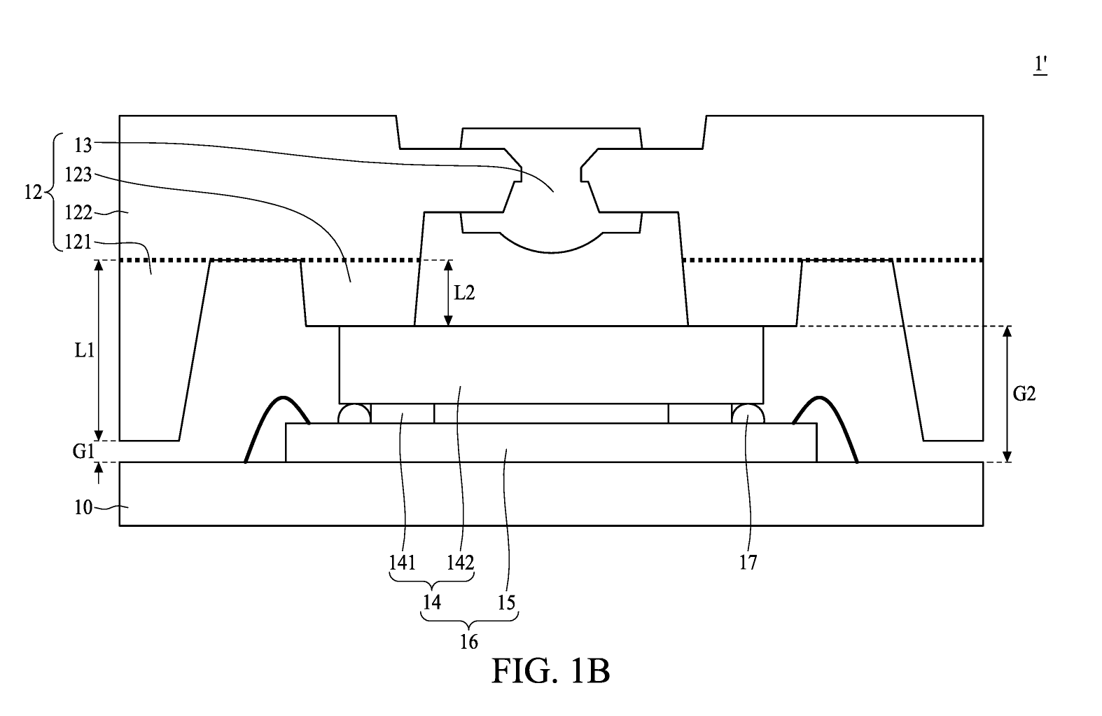

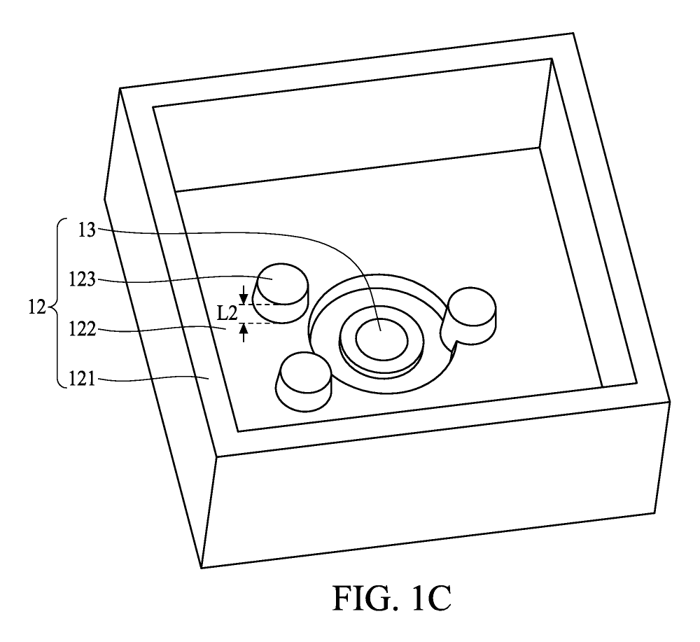

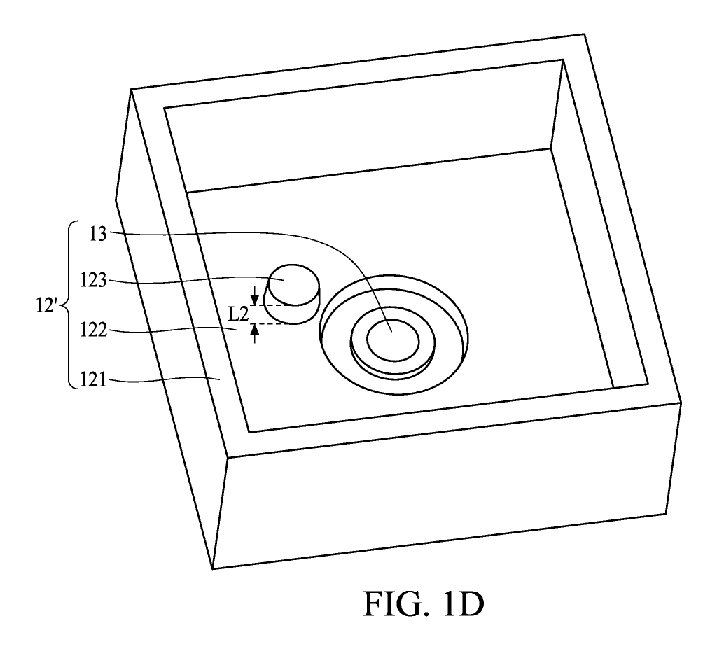

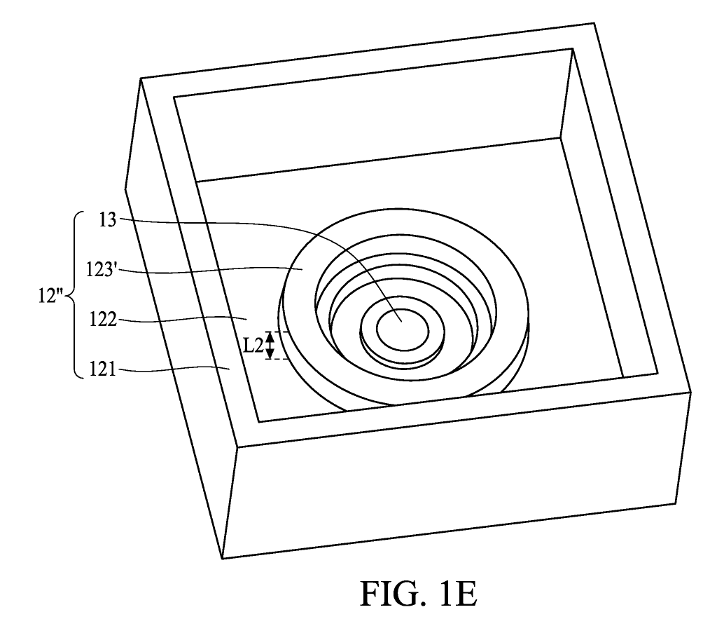

FIG. 1A is a cross-sectional view of a semiconductor device package 1 in accordance with some embodiments of the present disclosure. The semiconductor device package 1 includes a carrier 10, an adhesive material 11, a lid 12, a support 14, and a semiconductor device 15.

The carrier 10 may include circuitry. The carrier 10 may include a redistribution structure.

The semiconductor device 15 is disposed on the carrier 10. The semiconductor device 15 is electrically connected to the circuitry of the carrier 10 through a conductive wire (not denoted in FIG. 1A). The semiconductor device 15 may include an optical die, such as a complementary metal oxide semiconductor (CMOS) image sensor or the like.

The support 14 is disposed on the semiconductor device 15. The support 14 may be attached to the semiconductor device 15. The support 14 may be attached to the semiconductor device 15 by, for example, an adhesive 17. The support 14 may protect the semiconductor device 15 from damage. The support 14 may protect the semiconductor device 15 from contamination (e.g. moisture, particles, dust, etc.).

The support 14 includes at least one spacer 141. The support 14 includes a plate 142. The spacer 141 and the plate 142 may be formed in integrally as a monolithic structure. The spacer 141 and the plate 142 constitute at least a portion of the support 14. The support 14 includes a transparent material (e.g. a material that is substantially transmissive (such as about 80% or more transmissive, about 90% or more transmissive, or about 95% or more transmissive) to light that the semiconductor device 15 is configured to process or emit).

The spacer 141 is in contact with the semiconductor device 15. The plate 142 covers at least a portion of the semiconductor device 15. The plate 142 covers a sensing area of the semiconductor device 15. The plate 142 may include or may be coated with one or more optical filters. The adhesive 17 is disposed adjacent to the spacer 141. The adhesive 17 surrounds the spacer 141. The spacer 141 prevents the adhesive 17 from entering the sensing area of the semiconductor device 15. The support 14 and the semiconductor device 15 constitute at least a portion of a semiconductor device module 16. The semiconductor device module 16 may also include the adhesive 17.

The lid 12 is disposed on the semiconductor device module 16. The lid 12 is disposed on the plate 142. The lid 12 covers and surrounds the semiconductor device module 16. The lid 12 is disposed on the semiconductor device 15. The lid 12 is disposed on the support 14. The lid 12 is in contact with the support 14. The lid 12 is in contact with the plate 142.

The lid 12 is spaced from the carrier 10 by a gap/distance G1. The lid 12 is spaced from the carrier 10 by the adhesive material 11. The lid 12 includes a base portion 122. The lid 12 includes an extension portion (also referred to herein as a pin) 121. The lid 12 includes an extension portion (also referred to herein as a pin) 123. The lid 12 includes a transparent portion 13. Although it is not illustrated, the lid 12 may define a vent hole. The lid 12 may include a transparent material (e.g. a material that is substantially transmissive (such as about 80% or more transmissive, about 90% or more transmissive, or about 95% or more transmissive) to light that the semiconductor device 15 is configured to process or emit). The lid 12 may include an opaque material (e.g. a material having a transmittance of about 20% or less, about 10% or less, or about 5% or less for light that the semiconductor device 15 is configured to process or emit).

The transparent portion 13 may include a lens. The transparent portion 13 may include a plate. The transparent portion 13 may be integrated into the lid 12. The transparent portion 13 and the lid 12 may be formed integrally as a monolithic structure. The transparent portion 13 may be embedded or disposed in the base portion 122. The transparent portion 13 may include, for example, but is not limited to, a convex portion, a concave portion, and/or a planar portion.

The base portion 122 covers at least a portion of the semiconductor device module 16. The base portion 122 may have a substantially planar bottom surface. The extension portion 121 extends from the base portion 122 of the lid 12 (e.g. from the bottom surface of the base portion 122) toward the carrier 10 and has a length L1. The extension portion 123 extends from the base portion 122 of the lid 12 (e.g. from the bottom surface of the base portion 122) toward the carrier 10 and toward the semiconductor device 15 and has a length L2. The length L1 of the extension portion 121 is greater than the length L2 of the extension portion 123 (e.g. by a factor of about 1.5 or more, about 2 or more, or about 3 or more). The extension portion 123 may have a length L2 which is substantially equal to a focal length of the transparent portion 13. The extension portion 123 is in contact with the semiconductor device module 16. The extension portion 123 is in contact with the support 14. The extension portion 123 abuts the semiconductor device module 16. The extension portion 123 is spaced from the carrier 10 by a gap/distance G2. The extension portion 121 is spaced from the carrier 10 by the gap/distance G1. The gap/distance G2 is greater than the gap/distance G1 (e.g. by a factor of about 2 or more, about 3 or more, or about 4 or more). The gap/distance G1 may be smaller than about 200 micrometers (μm) (e.g. may be about 190 μm or less, about 180 μm or less, or about 170 μm or less).

An adhesive material 11 is disposed between the extension portion 121 of the lid 12 and the carrier 10. The adhesive material 11 substantially fills the gap/distance G1. The adhesive material 11 surrounds the semiconductor device 15. The adhesive material 11 is used to bond the lid 12 to the carrier 10. In some other embodiments, the adhesive material 11 may separate the extension portion 121 of the lid 12 and the carrier 10.

The lid 12 abuts the support 14. The lid 12 is in contact with the support 14. The effective optical path or focal distance between the transparent portion 13 and the semiconductor device 15 may depend on the length L2 of the extension portion 123. The effective optical path or focal distance between the transparent portion 13 and the semiconductor device 15 may depend on (may be set as a function of) the thickness of the support 14. Such arrangements may mitigate or minimize optical issues caused by assembly misalignment/deviation. Such arrangements may mitigate or minimize optical issues caused by deviation from a manufacturing tolerance/deviation. Manufacturing deviations of the support 14 may affect optical performance of the semiconductor device package 1. Manufacturing deviations of the extension portion 123 may affect optical performance of the semiconductor device package 1. Manufacturing tolerances of the extension portion 123 may be in a range from approximately 10 μm to approximately 20 μm. Manufacturing tolerances of the transparent plate 142 may be in a range from approximately 5 μm to approximately 10 μm. Manufacturing tolerances of the spacer 141 may be in a range from approximately 5 μm to approximately 10 μm. Total manufacturing tolerances of the semiconductor device package 1 may be in a range from approximately 20 μm to approximately 40 μm.

Manufacturing tolerances of the extension portion 121 may be in a range from approximately 20 μm to approximately 30 μm. Notably, since the size of the extension portion 123 (which can function as a focal length pin) is less than the size of the extension portion 121, the deviations of the extension portion 123 can be made small.

FIG. 1B is a cross-sectional view of a semiconductor device package 1′ in accordance with some embodiments of the present disclosure. The structure of the semiconductor device package 1′ of FIG. 1B is similar to the semiconductor device package 1 of FIG. 1A, except that the adhesive material 11 is omitted. A lid 12 is disposed on a semiconductor device module 16 by the supporting of an extension portion 123 of the lid 12. The lid 12 is placed on a support 14. An extension portion 121 of the lid 12 is designed to be spaced from the carrier 10 by a gap/distance G1. An extension portion 123 of the lid 12 is designed to be spaced from the carrier 10 by a gap/distance G2. The gap/distance G2 is greater than the gap/distance G1 (e.g. by a factor of about 2 or more, about 3 or more, or about 4 or more). The gap/distance G1 may be smaller than about 200 μm (e.g. may be about 190 μm or less, about 180 μm or less, or about 170 μm or less).

FIG. 1C is a perspective view of a lid 12 of a semiconductor device package 1 according to some embodiments of the present disclosure. The lid 12 includes an extension portion 121, a base portion 122, three extension portions 123, and a transparent portion 13. The extension portions 123 extend from the lid 12. The extension portions 123 have the substantially same length/height L2. In some embodiments, the sizes (e.g. a diameter, or a height) of the three extension portions 123 are the same. The locations of the extension portions 123 on a bottom surface of the base portion 122 may be set as appropriate.

FIG. 1D is a perspective view of a lid 12′ according to some embodiments of the present disclosure. The structure of the lid 12′ of FIG. 1D is similar to the lid 12 of FIG. 1C, except that the lid 12′ has one extension portion 123. This arrangement may decrease the cost of the lid 12′. The arrangement of the extension portion 123 may help to avoid or mitigate a pop-corn effect (e.g. an inflation due to a temperature change that can cause deformation or displacement of one or more components). The arrangement of the extension portion 123 may help to avoid the extension portion 123 affecting incident light.

FIG. 1E is a perspective view of a lid 12″ according to some embodiments of the present disclosure. The structure of the lid 12″ of FIG. 1E is similar to the lid 12 of FIG. 1C, except that the lid 12″ has an extension portion 123′ surrounding a transparent portion 13. A shape of the extension portion 123′ may be a circle, an ellipse, a rectangle, or a polygon, for example. The arrangement of the extension portion 123′ may let the lid 12″ be stably arranged on a semiconductor device module 16.

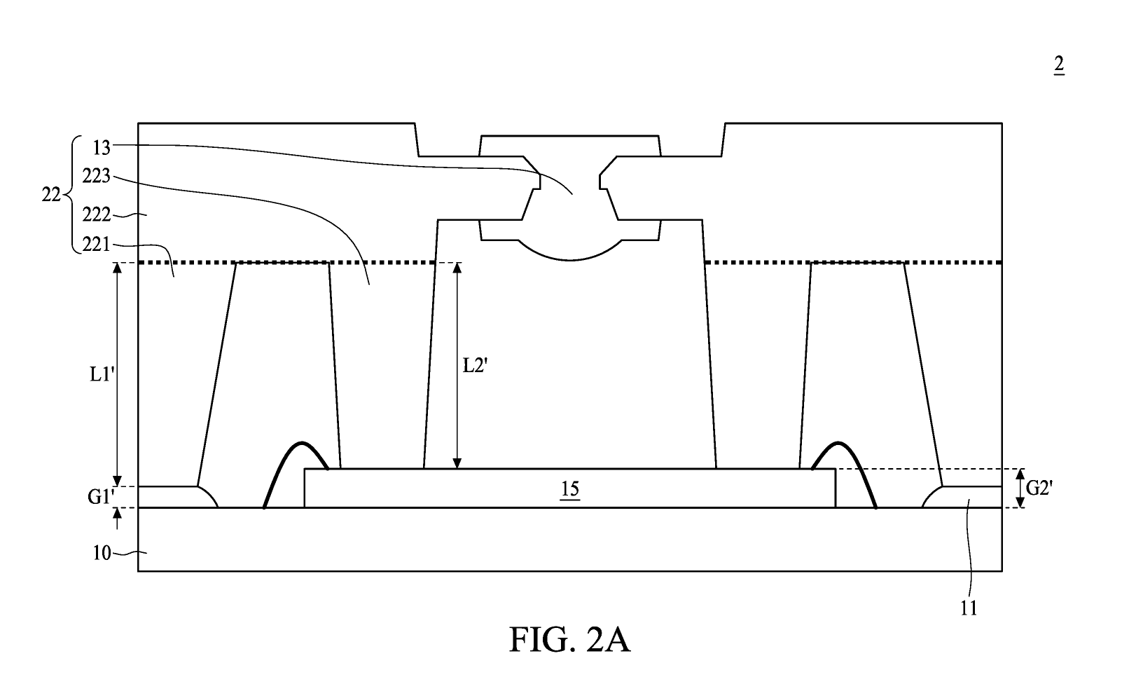

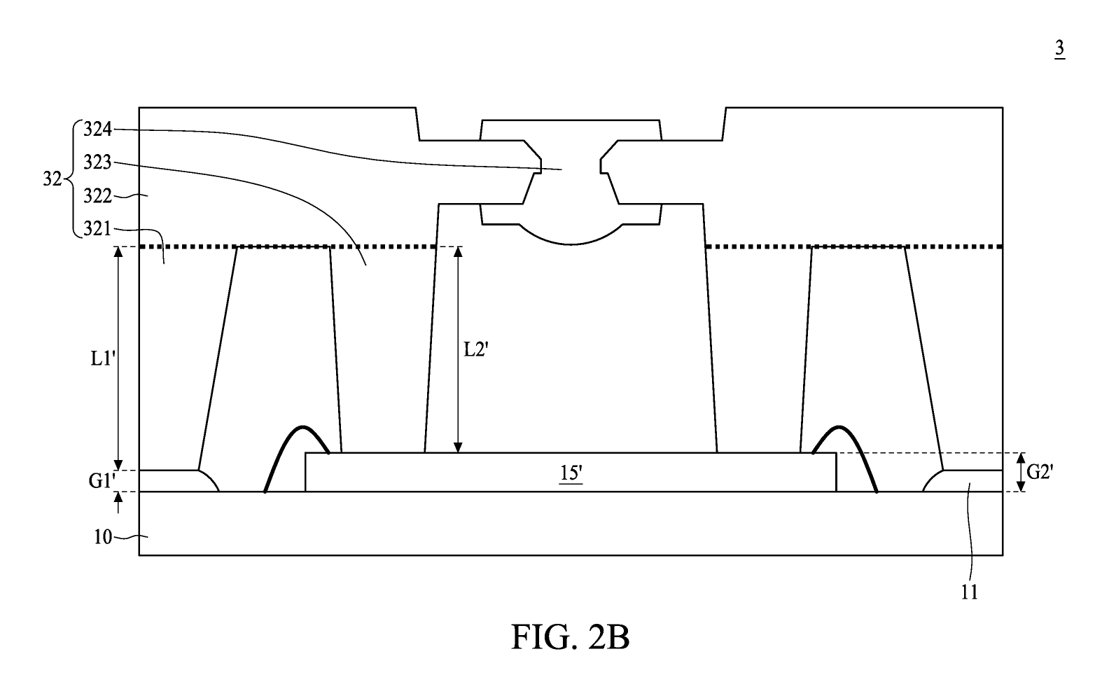

FIG. 2A is a cross-sectional view of a semiconductor device package 2 in accordance with some embodiments of the present disclosure. The semiconductor device package 2 includes a carrier 10, an adhesive material 11, a lid 22, and a semiconductor device 15.

The carrier 10 may include circuitry. The carrier 10 may include a redistribution structure.

The semiconductor device 15 is disposed on the carrier 10. The semiconductor device 15 is electrically connected to the circuitry of the carrier 10 through a conductive wire (not denoted in FIG. 2A). The semiconductor device 15 may include an optical die, such as a CMOS image sensor or the like.

The lid 22 is disposed on the semiconductor device 15. The lid 22 is in contact with the semiconductor device 15. The lid 22 covers and surrounds the semiconductor device 15.

The lid 22 is spaced from the carrier 10 by a gap/distance G1′. The lid 22 is spaced from the carrier 10 by the adhesive material 11. The lid 22 includes a base portion 222. The lid 22 includes an extension portion (also referred to herein as a pin) 221. The lid 22 includes an extension portion (also referred to herein as a pin) 223. The lid 22 includes a transparent portion 13. Although it is not illustrated, the lid 22 may define a vent hole. The lid 22 may include a transparent material (e.g. a material that is substantially transmissive (such as about 80% or more transmissive, about 90% or more transmissive, or about 95% or more transmissive) to light that the semiconductor device 15 is configured to process or emit). The lid 22 may include an opaque material (e.g. a material having a transmittance of about 20% or less, about 10% or less, or about 5% or less for light that the semiconductor device 15 is configured to process or emit).

The transparent portion 13 may include a lens. The transparent portion 13 may include a plate. The transparent portion 13 may be integrated into the lid 22. The transparent portion 13 and the lid 22 may be formed integrally as a monolithic structure. The transparent portion 13 may be embedded or disposed in the base portion 222. The transparent portion 13 may include, for example, but is not limited to, a convex portion, a concave portion, and/or a planar portion.

The base portion 222 covers at least a portion of the semiconductor device 15. The base portion 122 may have a substantially planar bottom surface. The extension portion 221 extends from the base portion 222 of the lid 22 (e.g. from the bottom surface of the base portion 222) toward the carrier 10 and has a length L1′. The extension portion 223 extends from the base portion 222 of the lid 22 (e.g. from the bottom surface of the base portion 222) toward the carrier 10 and toward the semiconductor device 15 and has a length L2′. The length L1′ of the extension portion 221 is greater than the length L2′ of the extension portion 223 (e.g. by a factor of about 1.5 or more, about 2 or more, or about 3 or more). The extension portion 223 may have a length L2′ which is substantially equal to a focal length of the transparent portion 13. The extension portion 223 is in contact with the semiconductor device 15. The extension portion 223 abuts the semiconductor device 15. The extension portion 223 is spaced from the carrier 10 by a gap/distance G2′. The gap/distance G2′ is greater than the gap/distance G1′ (e.g. by a factor of about 1.5 or more, about 2 or more, or about 3 or more). The extension portion 221 is spaced from the carrier 10 by the gap/distance G1′. The gap/distance G1′ may be smaller than 200 μm (e.g. may be about 190 μm or less, about 180 μm or less, or about 170 μm or less).

An adhesive material 11 is disposed between the extension portion 221 of the lid 22 and the carrier 10. The adhesive material 11 substantially fills the gap/distance G1′. The adhesive material 11 surrounds the semiconductor device 15. The adhesive material 11 is used to bond the lid 22 to the carrier 10. In some embodiments, the adhesive material 11 may discontinuously surround the semiconductor device 15.

The lid 22 abuts the semiconductor device 15. The lid 22 is in contact with the semiconductor device 15. The effective optical path or focal distance between the transparent portion 13 and the semiconductor device 15 may depend on the length L2′ of the extension portion 223. Such arrangements may mitigate or minimize optical issues caused by assembly misalignment/deviation. Such arrangements may mitigate or minimize optical issues caused by deviation from a manufacturing tolerance. Manufacturing deviations of the extension portion 223 (which can function as a focal length pin) may affect optical performance of the semiconductor device package 2. Manufacturing tolerances of the extension portion 223 may be in a range from approximately 10 μm to approximately 20 μm. Total manufacturing tolerances of the semiconductor device package 2 may be in a range from approximately 10 μm to approximately 20 μm.

Manufacturing tolerances of the extension portion 221 may be in a range from approximately 20 μm to approximately 30 μm. Since the size of the extension portion 223 is less than the size of the extension portion 221, the deviations of the extension portion 223 can be made small.

FIG. 2B is a cross-sectional view of a semiconductor device package 3 in accordance with some embodiments of the present disclosure. The semiconductor device package 3 includes a carrier 10, an adhesive material 11, a lid 32, and a semiconductor device 15. The structure of the semiconductor device package 3 of FIG. 2B is similar to the semiconductor device package 2 of FIG. 2A and includes a lid 32. The semiconductor device 15 of the semiconductor device package 3 is an emitter. The lid 32 includes a transparent material (e.g. a material that is substantially transmissive (such as about 80% or more transmissive, about 90% or more transmissive, or about 95% or more transmissive) to light that the semiconductor device 15 is configured to emit).

The lid 32 includes a base portion 322. The lid 32 includes an extension portion 321. The lid 32 includes an extension portion 323. The lid 32 includes a transparent portion 324. The extension portion 321, the base portion 322, the extension portion 323, and the transparent portion 324 may be formed integrally as a monolithic structure.

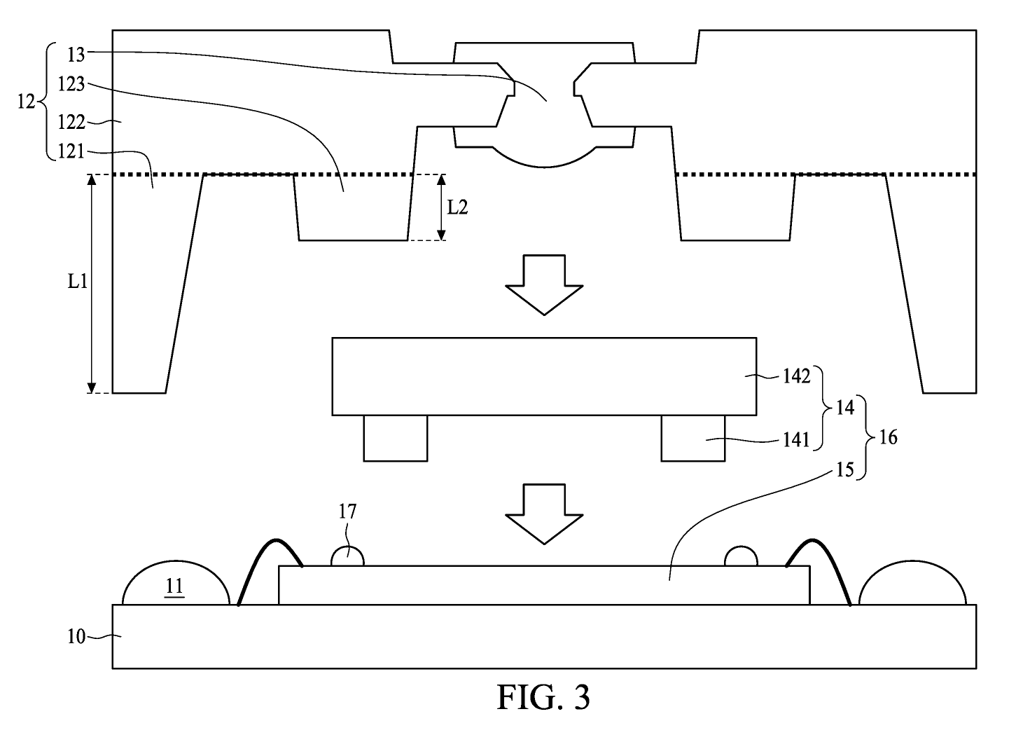

FIG. 3 illustrates a method of manufacturing a semiconductor device package 1 according to some embodiments of the present disclosure. A carrier 10 is provided and a semiconductor device 15 is bonded and wire bonded to the carrier 10. The semiconductor device 15 may be an optical die. In some embodiments, the semiconductor device 15 may be an image sensor. An adhesive 17 is disposed or provided on the semiconductor device 15.

An adhesive material 11 is applied to the carrier 10. The applied adhesive material 11 may be a soft gel or glue. A height/thickness or volume of the applied adhesive material 11 is large enough to ensure the applied adhesive material 11 contacts a lid 12 when the lid 12 is attached to a support 14 on the semiconductor device 15. In one or more embodiments, the height/thickness of the applied adhesive material 11 is larger than a gap G1 of the assembled semiconductor device package 1 (and, for example the applied adhesive material 11 is compressed during the manufacture process).

The support 14 is attached to the semiconductor device 15. The support 14 includes a spacer 141 and a transparent plate 142. The adhesive 17 is adjacent to the spacer 141. The adhesive 17 may help to secure the support 14 to the semiconductor device 15. The support 14 and the semiconductor device 15 constitute at least a portion of a semiconductor device module 16.

The lid 12 is attached to the support 14. The lid 12 includes an extension portion 121, a base portion 122, an extension portion 123, and a transparent portion 13. The transparent portion 13 may be pre-formed via an injecting operation. The transparent portion 13 is embedded in the base portion 122 of the lid 12. The extension portion 123 is directly in contact with the transparent plate 142 of the support 14. The lid 12 is disposed on the support 14 via the extension portion 123. The extension portion 121 is adjacent to the carrier 10. The extension portion 121 is spaced from the carrier 10 by a gap/distance G1. The extension portion 123 is spaced from the carrier 10 by a gap/distance G2. The gap/distance G2 is greater than the gap/distance G1 (e.g. by a factor of about 2 or more, about 3 or more, or about 4 or more). The gap/distance G1 may be smaller than 200 μm (e.g. may be about 190 μm or less, about 180 μm or less, or about 170 μm or less). The extension portion 121 is in contact with the adhesive material 11. The adhesive material 11 is pressed by the extension portion 121. The adhesive material 11 fills the gap/distance G1. The adhesive material 11 may be cured. A height or thickness of the cured adhesive material 11 may be larger than G1.

The lid 12 includes an opaque material (e.g. a material having a transmittance of about 20% or less, about 10% or less, or about 5% or less for light that the semiconductor device 15 is configured to process or emit). The extension portion 121, the base portion 122, and the extension portion 123 may be integrally formed as a monolithic structure. The extension portion 121, the base portion 122, and the extension portion 123 include an opaque material (e.g. a material having a transmittance of about 20% or less, about 10% or less, or about 5% or less for light that the semiconductor device 15 is configured to process or emit). In some embodiments, the lid 12 may include a plurality of extension portions 123 that protrude toward the semiconductor device module 16.

The extension portion 121 has a length L1. The extension portion 123 has a length L2. The length L1 of the extension portion 121 is greater than the length L2 of the extension portion 123 (e.g. by a factor of about 1.5 or more, about 2 or more, or about 3 or more). The length L1 and the length L2 could be set according to design specifications. A focal distance between the transparent portion 13 and the semiconductor device 15 can be controlled by setting the length L2 of the extension portion 123.

Manufacturing tolerances of the extension portion 123 may be in a range from approximately 10 μm to approximately 20 μ. Manufacturing tolerances of the transparent plate 142 may be in a range from approximately 5 μm to approximately 10 μm. Manufacturing tolerances of the spacer 141 may be in a range from approximately 5 μm to approximately 10 μm. Total manufacturing tolerances of the semiconductor device package 1 may be in a range from approximately 20 μm to approximately 40 μm.

The manufacturing method of FIG. 3 may be similarly applied to manufacture the semiconductor device package 1′ of FIG. 1B.

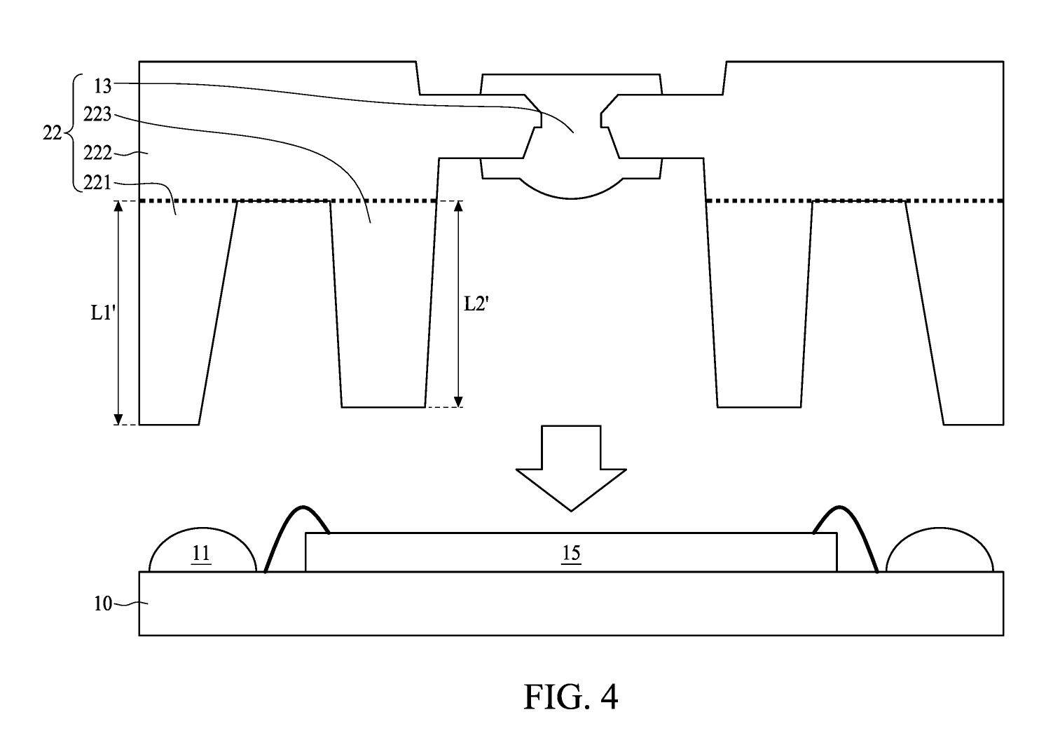

FIG. 4 illustrates a method of manufacturing a semiconductor device package 2 according to some embodiments of the present disclosure. FIG. 4 may be similarly applied to manufacture the semiconductor device package 3 of FIG. 2B. A carrier 10 is provided and a semiconductor device 15 is bonded and wire bonded to the carrier 10. The semiconductor device 15 may be an optical die. In some embodiments, the semiconductor device 15 may be an image sensor.

An adhesive material 11 is applied to the carrier 10. The applied adhesive material 11 may be a soft gel or glue. A height/thickness or volume of the applied adhesive material 11 is large enough to ensure the applied adhesive material 11 contacts a lid 22 when the lid 22 is attached to the semiconductor device 15. In one or more embodiments, the height/thickness of the applied adhesive material 11 is larger than a gap G1′ of the assembled semiconductor device package 3 (and, for example the applied adhesive material 11 is compressed during the manufacture process).

The lid 22 is attached to the semiconductor device 15. The lid 22 includes an extension portion 221, a base portion 222, an extension portion 223, and a transparent portion 13. The transparent portion 13 may be pre-formed in the lid 22 via an injecting operation. The transparent portion 13 is embedded in the base portion 222 of the lid 22. The extension portion 223 is directly in contact with the semiconductor device 15. The lid 22 is disposed on the semiconductor device 15 via the extension portion 223. The extension portion 221 is adjacent to the carrier 10. The extension portion 221 is spaced from the carrier 10 by a gap/distance G1′. The extension portion 223 is spaced from the carrier 10 by a gap/distance G2′. The gap/distance G2′ is greater than the gap/distance G1′ (e.g. by a factor of about 2 or more, about 3 or more, or about 4 or more). The extension portion 221 is in contact with the adhesive material 11. The adhesive material 11 is pressed by the extension portion 221. The adhesive material 11 fills the gap/distance G1′. The adhesive material 11 is cured. A thickness of the cured adhesive material 11 may be larger than G1′.

The lid 22 includes an opaque material (e.g. a material having a transmittance of about 20% or less, about 10% or less, or about 5% or less for light that the semiconductor device 15 is configured to process or emit). The extension portion 221, the base portion 222, and the extension portion 223 may be integrally formed as a monolithic structure. The extension portion 221, the base portion 222, and the extension portion 223 include an opaque material (e.g. a material having a transmittance of about 20% or less, about 10% or less, or about 5% or less for light that the semiconductor device 15 is configured to process or emit). In some embodiments, the material of the lid 22 may include a transparent material (e.g. a material that is substantially transmissive (such as about 80% or more transmissive, about 90% or more transmissive, or about 95% or more transmissive) to light that the semiconductor device 15 is configured to process or emit). The semiconductor device 15 may be an emitter.

The extension portion 221 has a length L1′. The extension portion 223 has a length L2′. The length L1′ of the extension portion 221 is greater than the length L2′ of the extension portion 223 (e.g. by a factor of about 1.5 or more, about 2 or more, or about 3 or more). The length L and the length L2′ can be set according to design specifications. A focal distance between the transparent portion 13 and the semiconductor device 15 can be controlled by setting the length L2′ of the extension portion 223.

Manufacturing tolerances of the extension portion 223 may be in a range from approximately 10 μm to approximately 20 μm. Total manufacturing tolerances of the semiconductor device package 2 may be in a range from approximately 10 μm to approximately 20 μm.

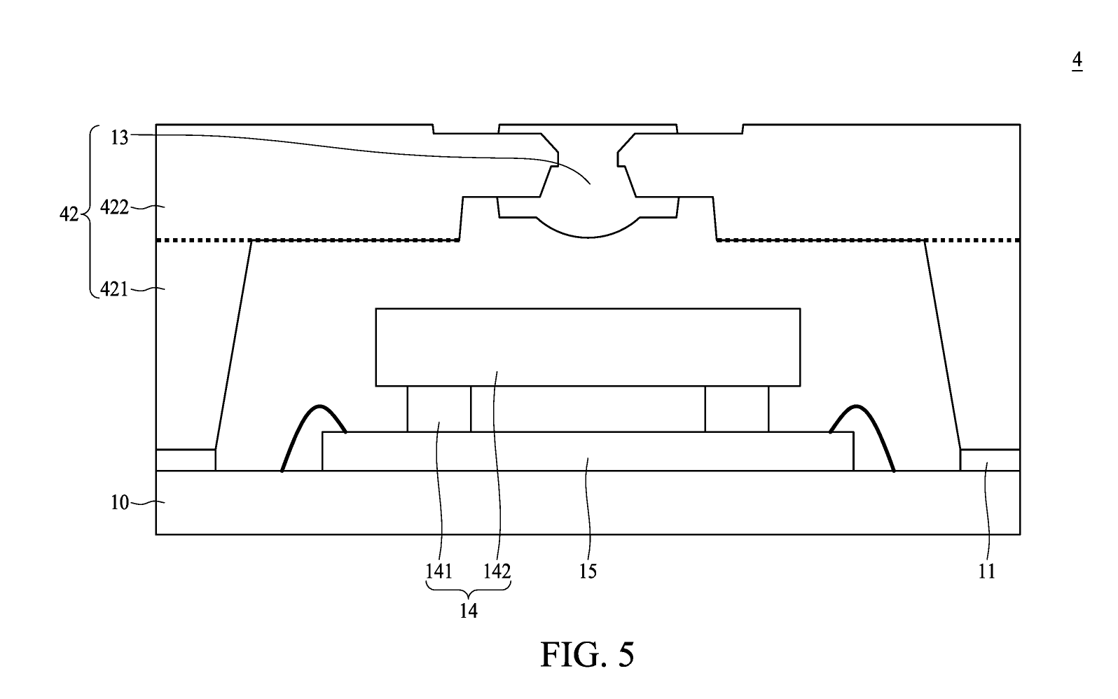

FIG. 5 illustrates a cross-sectional view of a comparative semiconductor device package 4. The semiconductor device package 4 includes a carrier 10, an adhesive material 11, a lid 42, a support 14, and a semiconductor device 15.

The semiconductor device 15 is disposed on the carrier 10 via an adhesive. The semiconductor device 15 is an image sensor.

The support 14 is disposed on the semiconductor device 15. The support 14 includes a spacer 141 and a transparent plate 142. The spacer 141 contacts the semiconductor device 15. The transparent plate 142 protects a sensing area of the semiconductor device 15.

The lid 42 is disposed on the carrier 10. The lid 42 abuts the carrier 10. The lid 42 includes an extension portion 421 and a base portion 422, and a transparent portion 13. The transparent portion 13 includes a lens. The lid 42 includes an opaque material (e.g. a material having a transmittance of about 20% or less, about 10% or less, or about 5% or less for light that the semiconductor device 15 is configured to process or emit).

The extension portion 421 extends from the base portion 422 toward the carrier 10. The extension portion 421 is disposed on the carrier 10. An adhesive material 11 is disposed between the extension portion 421 of the lid 42 and the carrier 10. The lid 12 is attached to the carrier 10. The adhesive material 11 is pressed by the extension portion 421. During manufacture, the adhesive material 11 is cured. A thickness of the cured adhesive material 11 is in a range from approximately 10 μm to approximately 100 μm. Such a thickness of the cured adhesive material 11 can help to ensure that the lid 42 is disposed in close proximity to the carrier 10. Accordingly, the lid 42 can be secured to the carrier 10 without detaching from the carrier 10.

The effective optical path or focal distance between the transparent portion 13 and the semiconductor device 15 may depend on multiple features of the lid 42 (including a length of the extension portion 421). The effective optical path or focal distance between the transparent portion 13 and the semiconductor device 15 may depend on the thickness of the support 14. The effective optical path or focal distance between the transparent portion 13 and the semiconductor device 15 may depend on features of the semiconductor device 15. Such arrangements may make it difficult to mitigate optical issues caused by assembly misalignments/deviations. Such arrangements may make it difficult to mitigate optical issues caused by deviations from manufacturing tolerances, because manufacturing tolerances of the lid 42, the support 14, and the semiconductor device 15 may affect the assembly misalignments/deviations. Manufacturing tolerances of the extension portion 421 may be in a range from approximately 20 μm to approximately 30 μm. Thus, manufacturing tolerances of the lid 42 may be in a range from approximately 20 μm to approximately 30 μm. Manufacturing tolerances of the adhesive material 11 may be smaller than approximately 50 μm. Manufacturing tolerances of the semiconductor device 15 may be approximately 10 μm. Manufacturing tolerances of an adhesive thickness for bonding the semiconductor device 15 to the carrier 10 may be smaller than approximately 50 μm.

By way of comparison, in one or more embodiments described herein the effective optical path or focal distance between the transparent portion 13 and the semiconductor device 15 may depend on an extension portion of a lid that is disposed on a semiconductor device (e.g. the extension portion 123 of the lid 12 disposed on the semiconductor device 15), which can provide for readily controlling or setting the effective optical path or focal distance between the transparent portion 13 and the semiconductor device 15. One or more embodiments described herein may provide for improved manufacturing tolerances.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within micrometers of lying along a same plane, such as within 40 μ, within 30 μm, within 20 μm within 10 μm, or within 1 μm of lying along the same plane. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

What is claimed is:

1. A semiconductor device package, comprising:
a carrier;
a semiconductor device disposed on the carrier; and
a lid disposed on the semiconductor device, the lid being spaced from the carrier by a first distance, the lid comprising:
a base portion;
a first pin extending from the base portion toward the semiconductor device, the first pin being spaced from the carrier by a second distance; and
a transparent portion.

2. The semiconductor device package of claim 1, wherein the second distance is greater than the first distance.

3. The semiconductor device package of claim 2, wherein the first distance is smaller than approximately 200 μm.

4. The semiconductor device package of claim 1, wherein the first pin contacts the semiconductor device.

5. The semiconductor device package of claim 1, further comprising a support disposed on the semiconductor device.

6. The semiconductor device package of claim 5, wherein the first pin contacts the support.

7. The semiconductor device package of claim 5, wherein the support comprises a spacer that contacts the semiconductor device.

8. The semiconductor device package of claim 7, further comprising an adhesive disposed on the semiconductor device and adjacent to the spacer.

9. The semiconductor device package of claim 1, further comprising an adhesive disposed between the lid and the carrier.

10. The semiconductor device package of claim 1, wherein the lid further comprises a second pin extending from the base portion toward the semiconductor device, wherein a height of the first pin is substantially equal to a height of the second pin.

11. The semiconductor device package of claim 1, wherein the semiconductor device is a photo sensor or an emitter.

12. The semiconductor device package of claim 1, wherein the lid comprises an opaque material.

13. The semiconductor device package of claim 1, wherein the lid comprises a transparent material.

14. The semiconductor device package of claim 1, wherein the transparent portion is embedded in the base portion.

15. The semiconductor device package of claim 14, wherein the base portion of the lid covers the semiconductor device and the lid surrounds the semiconductor device.

16. A semiconductor device package, comprising:
a carrier;
a semiconductor device module disposed on the carrier; and
a lid covering and surrounding the semiconductor device module, the lid comprising:
a base portion;
a pin extending from the base portion toward the semiconductor device module, the pin contacting the semiconductor device module; and
a transparent portion.

17. The semiconductor device package of claim 16, wherein the semiconductor device module comprises a support and a semiconductor device, and wherein the pin contacts the support of the semiconductor device module.

18. The semiconductor device package of claim 17, wherein the lid comprises an opaque material, and wherein the semiconductor device is a photo sensor.

19. The semiconductor device package of claim 17, wherein the support comprises a spacer contacting the semiconductor device.

20. The semiconductor device package of claim 19, wherein the semiconductor device module further comprises an adhesive disposed on the semiconductor device and adjacent to the spacer.

21. The semiconductor device package of claim 16, wherein the lid comprises a transparent material, and wherein the semiconductor device module is an emitter module.

22. The semiconductor device package of claim 16, wherein the lid further comprises an extension portion, and the extension portion of the lid is spaced from the carrier by a distance.

23. The semiconductor device package of claim 22, wherein the distance is smaller than approximately 200 μm.

24. The semiconductor device package of claim 22, further comprising an adhesive disposed between the extension portion of the lid and the carrier.

25. The semiconductor device package of claim 16, wherein the base portion and the pin are integrally formed.

26. A semiconductor device package, comprising:
a carrier;
a semiconductor device disposed on the carrier; and
a lid adjacent to the carrier, the lid comprising a base portion, a first extension portion with a first length, a second extension portion with a second length, and a transparent portion,
wherein the first extension portion and the second extension portion extend from the base portion toward the carrier, and
wherein the first length of the first extension portion is greater than the second length of the second extension portion.

27. A method for manufacturing a semiconductor device package, comprising:
providing a carrier and a semiconductor device module; and
providing a lid on the semiconductor device module, the lid being spaced from the carrier by a gap;
wherein the lid comprises a plurality of pins protruding toward the semiconductor device module, and
wherein the plurality of pins contact the semiconductor device module.

28. The method of claim 27, further comprising applying an adhesive on the carrier.

29. The method of claim 28, further comprising curing the adhesive to secure the lid to the carrier.

30. The method of claim 28, wherein the adhesive has a height and the height of the adhesive is greater than the gap.

31. The method of claim 27, wherein the lid comprises a transparent portion.
